(19) United States
(12) Patent Application Publication
(10) Pub. No.: US 2006/0038272 A1
(43) Pub. Date: Feb. 23, 2006

(54) Stacked wafer scale package

(75) Inventor: Darvin R. Edwards, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/919,691

(22) Filed: Aug. 17, 2004

(51) Int. Cl. H01L 23/02; H01L 23/52

(52) U.S. Cl. 257/686; 257/777

(57) ABSTRACT

A device comprising a first die enclosed in a wafer scale package, said first die adapted to mate with a printed circuit board (“PCB”) via solder bumps. The device further comprises a second die enclosed in a wafer scale package and electrically connected to a surface of the first die facing the PCB to form a die stack.

### BACKGROUND

In a “stacked die” integrated circuit (“IC”) package, two or more semiconductor dies are electrically connected by arranging each die on top of another die. Stacked die packaging technologies have gradually gained market acceptance for use in mobile phone and handheld device applications, where increased functionality, reduced form factor and lighter weight continue to be substantial driving forces. For example, companies such as Nokia® and Ericsson® regularly introduce mobile phones that are smaller, lighter and more useful than before. IC packages containing stacked dies are desirable because the stacked dies provide substantial functionality while occupying a minimum amount of printed circuit board (“PCB”) space.

A relatively small IC package is the “wafer scale” package. The wafer scale package is formed directly onto a die and generally is the same size as or only slightly larger than the die, resulting in relatively high package density and an efficient use of space. Conversely, a non-wafer scale package is not formed directly onto a die and is often larger than the die, resulting in relatively poor package density, an inefficient use of space and a package that is thus unnecessarily large. However, because wafer scale packages are built directly onto individual dies, it is generally not possible for a wafer scale package to contain multiple, stacked dies. Thus, it is difficult to reap from wafer scale packages the enhanced functionality of non-wafer scale packages containing multiple, stacked dies.

### BRIEF SUMMARY

The problems noted above are solved at least in part by a device comprising high-density, stacked wafer scale packages. In at least some embodiments, the device comprises a first die enclosed in a wafer scale package, said first die adapted to mate with a printed circuit board (“PCB”) via solder bumps. The device further comprises a second die enclosed in a wafer scale package and electrically connected to a surface of the first die facing the PCB to form a die stack.

### BRIEF DESCRIPTION OF THE DRAWINGS

For a detailed description of exemplary embodiments of the invention, reference will now be made to the accompanying drawings in which:

FIG. 1 shows a stacking configuration comprising a daughter die and a mother die stacked in accordance with a preferred embodiment of the invention;

FIG. 2a shows a stacking configuration comprising a plurality of daughter dies and a mother die stacked in accordance with another preferred embodiment of the invention;

FIG. 2b shows an exemplary process by which the stacking configurations of FIGS. 1, 2a and 5 may be implemented;

FIG. 3a shows another preferred stacking configuration comprising a plurality of daughter dies stacked upon a mother die comprising through-die vias;

FIG. 3b shows an exemplary process by which the stacking configuration of FIG. 3a may be implemented;

FIG. 3c shows a circuit-dense, stacking configuration comprising multiple daughter dies stacked against a mother die in accordance with additional preferred embodiments of the invention;

FIG. 3d shows a process by which the stacking configuration of FIG. 3c may be implemented;

FIG. 4a shows a stacking configuration comprising a plurality of granddaughter and daughter dies and a mother die stacked in accordance with additional embodiments of the invention;

FIG. 4b shows a process by which the stacking configuration of FIG. 4a may be implemented;

FIG. 5 shows another preferred stacking configuration comprising a daughter die electrically connected to a mother die by way of wirebonds; and

FIG. 6 shows a process by which the stacking configuration of FIG. 5 may be implemented.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or direct electrical connection. Thus, if a first device couples to a second device, that connection may be through a direct electrical connection, or through an indirect electrical connection via other devices and connections. Additionally, the term “die,” as used to describe the embodiments below, is intended to mean a die that is enclosed in a wafer-scale package.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

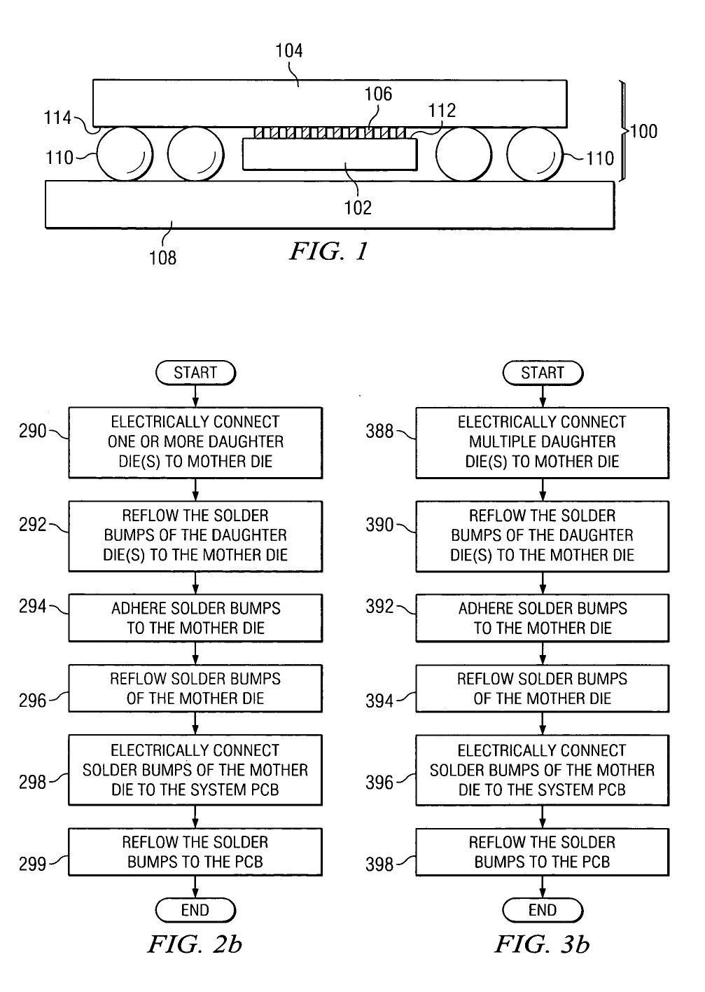

The physical configuration of a die stack dictates the amount of space the die stack occupies. Accordingly, described herein are various efficient wafer-scale package stacking configurations with circuit densities greater than those produced by traditional, non-wafer scale stacking techniques. FIG. 1 illustrates a daughter die 102 electrically connected to a mother die 104 by way of connections 106 to form a die stack 100. More specifically, the connections 106 electrically connect an active surface 112 of the daughter die 102 to an active surface 114 of the mother die 104. The connections 106 may comprise any electrically conductive material, such as solder bumps, anisotropic conduction adhesive, gold studs, or a combination thereof. In some embodiments, the daughter die 102 may be a logic die while the mother die 104 may be a memory die. The mother die 104 may electrically connect to a system printed circuit board (“PCB”) 108 by way of solder bumps 110. Although the solder bumps 110 may be of any size that adequately supports the mother die 104 and the daughter die 102, in at least some embodiments, the solder bumps 110 are approximately between 0.3 millimeters and 0.5 millimeters in pitch. In other embodiments, any electrically conductive material may be substituted for the solder bumps 110 (e.g., gold studs).

Because the daughter die 102 is electrically connected to the mother die 104, the daughter die 102 and the mother die 104 can freely exchange electrical signals. Signals also may be transferred between either of the dies 102, 104 and the system PCB 108 by way of the solder bumps 110. For example, a signal may travel from the daughter die 102 to the system PCB 108 by first passing through the connections 106 to the active surface 114, traveling along the active surface 114 to the solder bumps 110, and passing through the solder bumps 110 to the system PCB 108.

Stacking the wafer-scale packaged dies 102,104 as shown in FIG. 1 maximizes circuit functionality and minimizes or virtually eliminates wasted space. Generally, a wafer-scale package encapsulates a device fabricated on a semiconductor substrate wafer before the wafer is diced into individual chips or dies. The dies 102, 104 may be encapsulated into wafer-scale packages using any of a variety of techniques. One such wafer-scale packaging technique may begin by depositing any suitable type of polymer coating on a die as received from a wafer fabricator. Vias then may be opened in the polymer coating layer to expose die pads. A metal redistribution layer may be deposited on the entire wafer. This redistribution layer is patterned in accordance with design specifications. Solder bumps subsequently are adhered to specific locations on the redistribution layer, in accordance with design specifications. Finally, the wafer may be diced to produce individual chips or dies. Further information on wafer-scale packaging is provided in Adams, et al. (U.S. Pat. No. 5,323,051) and Yu (U.S. Pat. No. 6,341,070), which hereby are incorporated herein by reference.

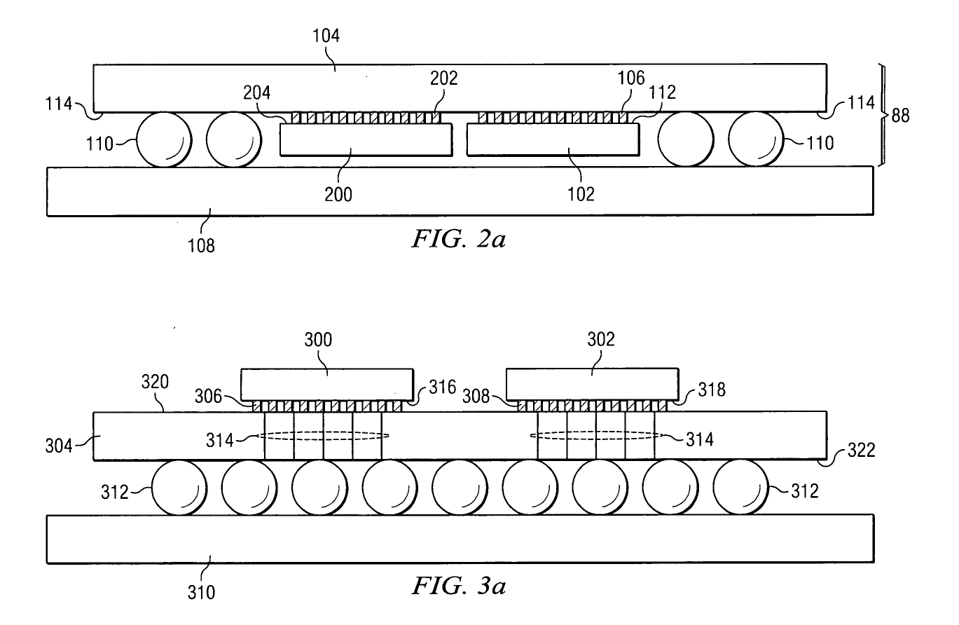

A second configuration permitting efficient wafer-scale package stacking is illustrated in FIG. 2a. Die stack 88 of FIG. 2a is generically equivalent to the die stack 100 shown in FIG. 1 with the exception of an additional daughter die 200 electrically connected to the mother die 104 by way of connections 202. The additional daughter die 200 provides the die stack 88 enhanced functionality over that of the configuration shown in FIG. 1. For example, the daughter die 200 may be a logic die that increases the overall speed of the die stack 88. Alternatively, the daughter die 200 may be a memory die, providing additional memory storage for the die stack 88. Electrical signals are transmitted between active surfaces 112, 204,114 of the dies 102, 200,104, respectively, in a manner similar to that of FIG. 1. In at least some embodiments, the die stack 88 may comprise three or more daughter dies, each daughter die stacked against the mother die 106.

FIG. 2b illustrates a process by which the configurations of FIGS. 1 and 2a may be implemented. The process may be executed by electrically connecting one or more daughter die to a surface of the mother die facing the system PCB. Specifically, the solder bumps of the daughter die(s) are aligned with receiving sites on the mother die. The receiving sites preferably are determined prior to beginning this process. The solder bumps of the daughter die(s) then may be reflowed to the mother die to establish solder joints, thereby creating electrical connections between the daughter die(s) and the mother die (block 292). Solder bumps then are adhered to a surface of the mother die facing the system PCB (block 294) and the solder bumps are reflowed (block 296). The solder bumps of the mother die subsequently are electrically connected to the system PCB by aligning the solder bumps with receiving pads on the PCB and reflowing the solder bumps to the PCB (block 298). The scope of disclosure is not limited to this particular sequence of steps. The steps may be re-arranged in any suitable fashion. For example, the step of block 298 may occur prior to the step of block 290.

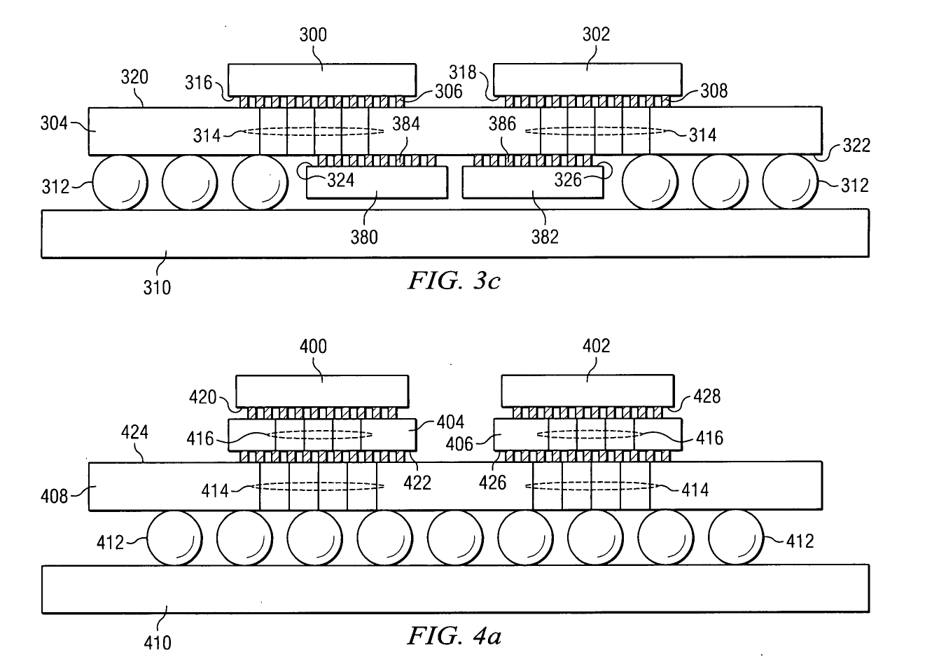

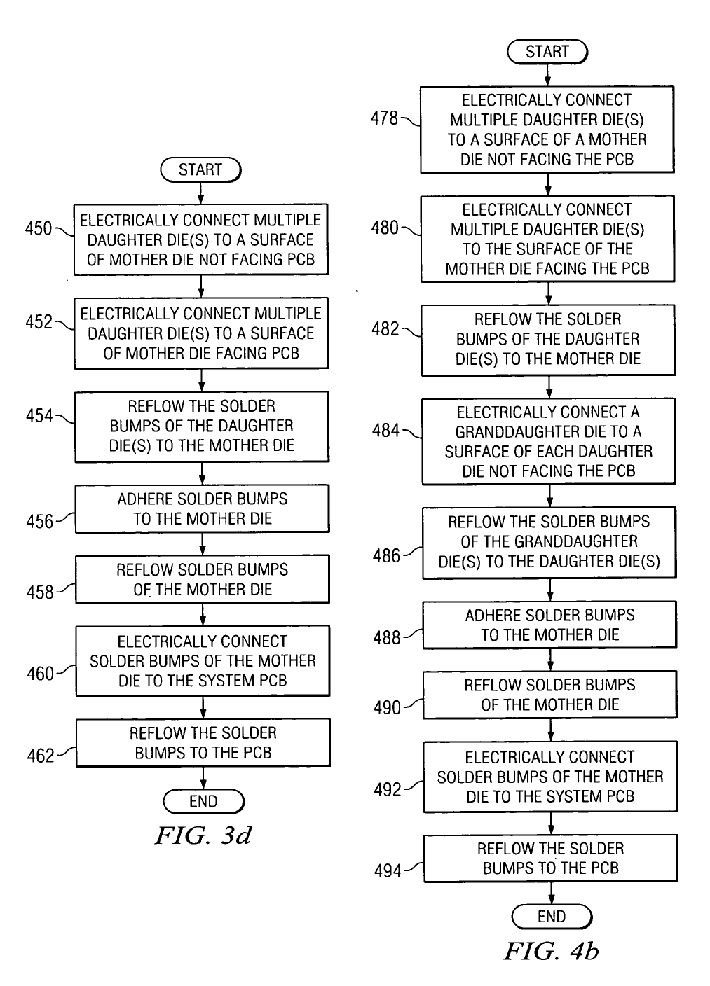

A through-die via is a conduit or pathway that carries electrical signals through a die. More specifically, signals on one side of a die can pass through a through-die via to emerge on another side of the die. Thus, electrical signals may be transmitted through an entire die stack comprising a plurality of dies by way of through-die vias formed in each die in the die stack. For example, through-die vias 314 may be used as shown in FIG. 3a to transmit electrical signals from daughter dies 300, 302, through the mother die 304, to the solder bumps 312. In this way, electrical signals are freely transmitted between active surfaces 316, 318 of the daughter dies 300, 302, an active surface 320 of the mother die 304, and the system PCB 310. Signals also can be transmitted between the daughter dies 300, 302 by way of the active surface 320 of the mother die 304. Furthermore, the surface 322 of the mother die 304 in contact with the solder bumps 312 may be covered in a metallization pattern (not shown) to enable signals to travel between the solder bumps 312 and the through-die vias 314. The solder bumps 312 preferably are between 0.3 mm and 0.5 mm in pitch. The scope of disclosure is not limited to this precise configuration. For example, in some embodiments, the surface 322 may be an active surface that faces the PCB 310, and the surface 320 may be electrically coupled to the daughter dies 300, 302.

FIG. 3b illustrates a process by which the configuration of FIG. 3a may be implemented. The process may be executed by first electrically connecting multiple daughter dies to a surface of the mother die not facing the system PCB. Specifically, the solder bumps of the daughter dies are aligned with receiving sites on the mother die and the solder bumps are reflowed (block 390). Additional solder bumps then are adhered to a surface of the mother die facing the system PCB (block 392) and are reflowed to the mother die to establish electrically conductive solder joints (block 394). The solder bumps of the mother die then are electrically connected to the system PCB by aligning the solder bumps with receiving pads on the PCB and reflowing the solder bumps (block 396).

The circuit density of the configuration may be increased with additional daughter dies, as shown in FIG. 3c. FIG. 3c shows a die configuration similar to that shown in FIG. 3a, but with additional daughter dies 380, 382 electrically connected to the mother die 304 by way of connections 384, 386, respectively. The through-die vias 314 are used to transmit signals between the daughter dies 300, 302 and the daughter dies 380, 382, as well as between the daughter dies 300, 302 and the system PCB 310. More specifically, signals are transmitted between any of the active surfaces 316, 318, 324, 326, 320 of the dies 300, 302, 380, 382, 304, respectively, by way of the through-die vias 314 and a metallization pattern (not shown) on a surface 322 of the mother die 304. For example, a signal may be transmitted from the active surface 316, through a through-die via 314, along the metallization pattern of the surface 322, and through the connectors 386 to the active surface 326 of the daughter die 382. Similarly, a signal may be transmitted from the system PCB 310, through one or more solder bumps 312, along the metallization pattern of the surface 322, through a through-die via 314, along the active surface 320, through the connectors 308 and to the active surface 318 of the daughter die 302. In some embodiments, the daughter dies 300, 302 may be optical coupling die wherein the active die surfaces 316, 318 face away from the mother die 304. In such embodiments, the daughter dies 300, 302 may comprise multiple through-die vias used to transfer information from the active die surfaces 316, 318 to the mother die 304 by way of the connections 306, 308.

FIG. 3d illustrates a process by which the die configuration of FIG. 3c may be implemented. The process is executed by electrically connecting multiple daughter dies to a surface of a mother die not facing the system PCB. Specifically, the solder bumps of the daughter dies are aligned with receiving sites on the mother die and are reflowed (block 450). Multiple daughter dies then are electrically connected to the surface of the mother die facing the system PCB by aligning solder bumps of the daughter dies with receiving sites in the metallization pattern of the mother die and reflowing the solder bumps (block 452). Additional solder bumps are adhered to the surface of the mother die facing the system PCB (block 454) and are reflowed to the mother die (block 456). The solder bumps of the mother die then are electrically connected to the system PCB by aligning the solder bumps to receiving pads on the PCB and reflowing the solder bumps to the PCB (block 458).

As previously explained, because through-die vias permit signals to pass through a die, any number of dies containing through-die vias may be included in a die stack. In this way, electrical conduits are available for the transmission of signals between any two dies in the die stack. FIG. 4a illustrates a three-level die stack comprising granddaughter dies 400, 402 stacked atop daughter dies 404, 406, respectively, in turn, stacked atop the mother die 408. The mother die 408 is supported and electrically connected to the system PCB 410 by solder bumps 412, which preferably are approximately between 0.3 mm and 0.5 mm in pitch. The daughter dies 404, 406 comprise through-die vias 416 and the mother die 408 comprises through-die vias 414. Generally, electrical signals are transmitted between any of the dies shown in FIG. 4a by way of the through-die vias 414, 416 and active die surfaces 420-428. Signals can be transferred between the granddaughter dies 400, 402; one granddaughter die and one daughter die; the daughter dies 404, 406, or any other possible combination of dies. For example, electrical signals can be transferred between either of the active surfaces 422, 426 of the daughter dies 404, 406 and the system PCB 410 by way of the through-die vias 414 and the solder bumps 412. Similarly, electrical signals may be transmitted between either of the active surfaces 420, 428 of the granddaughter dies 400, 402 and the system PCB 410 by way of the through-die vias 416, through-die vias 414 and the solder bumps 412.

FIG. 4b illustrates a process by which the configuration of FIG. 4a may be implemented. Specifically, the process comprises electrically connecting multiple daughter dies to a surface of the mother die not facing the system PCB by aligning solder bumps of the daughter dies with receiving sites on the mother die and reflowing the solder bumps (block 478). The mother die comprises a plurality of through-die vias and a metallization pattern on the surface facing the system PCB. The process further comprises the option of electrically connecting multiple daughter dies to the surface of the mother die facing the system PCB by aligning the solder bumps of the daughter dies with receiving sites in the metallization pattern of the mother die and reflowing the bumps (block 480). A granddaughter die subsequently is electrically connected to a surface of one or more daughter dies not facing the system PCB by aligning solder bumps of the granddaughter dies with receiving sites in a metallization pattern on the surface of the daughter dies not facing the system PCB and reflowing (block 482). Additional solder bumps then are adhered to the mother die (block 484) and are reflowed to the mother die (block 486). The solder bumps of the mother die then are electrically connected to the system PCB by aligning the solder bumps to receiving pads on the PCB and reflowing the bumps to the PCB (block 488). In at least some embodiments, any number of additional dies containing through-die vias may be stacked atop a preceding die, as desired. For example, a great-granddaughter die may be stacked atop the granddaughter die, a great-great-granddaughter die may be stacked atop the great-granddaughter die, and so forth.

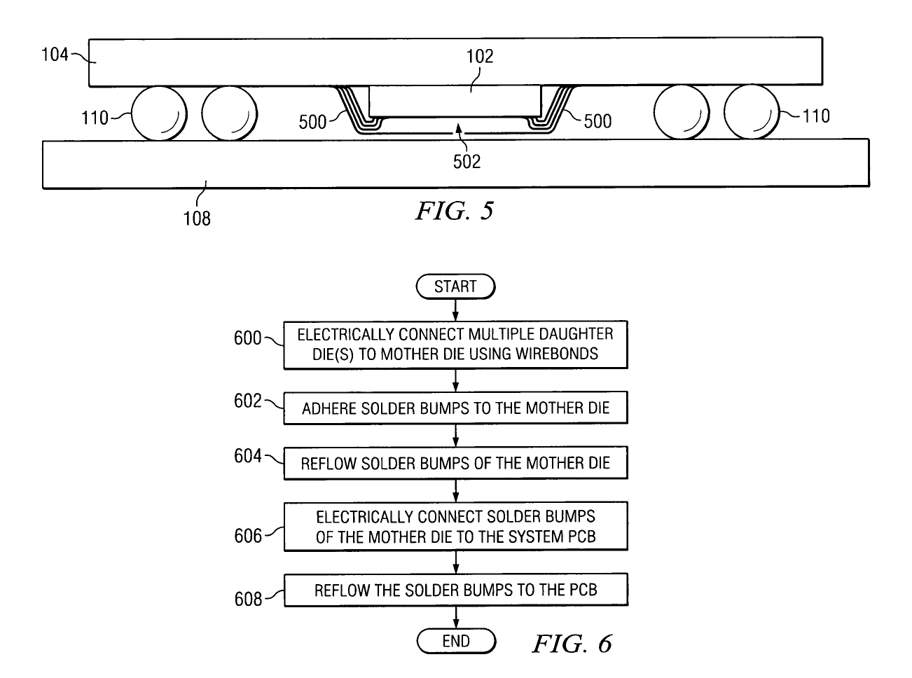

The configurations described herein are not limited to electrically connecting daughter dies and mother dies with solder bumps, gold studs or anisotropic conduction adhesives. Daughter dies and mother dies also may be electrically connected using wirebonds, as shown in FIG. 5. The configuration of FIG. 5 is generically equivalent to that shown in FIG. 1, with the exception of the electrical connection between the mother die 104 and the daughter die 102 being established by way of wirebonds 500 instead of the connections 106. Thus, electrical signals are transmitted between the mother die and the daughter die by way of the wirebonds 500. Electrical signals also may be transmitted between the mother die 104 and the system PCB 108 or the daughter die 102 and the system PCB 108 by way of the solder bumps 110. At least some embodiments comprising wirebonds 500 also may comprise potting or underfill 502 (e.g., epoxy or any appropriate material) as shown in FIG. 5.

A process implementing the configuration of FIG. 5 is shown in FIG. 6. The process may begin with using wirebonds to electrically connect one or more daughter dies to a surface of the mother die facing the PCB (block 600). Solder bumps then may be adhered to the surface of the mother die facing the PCB (block 602) and reflowed to the mother die (block 604). The solder bumps subsequently are electrically connected to the system PCB by reflowing the bumps to the PCB (block 606).

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A device, comprising:
a first die enclosed in a wafer scale package, said first die adapted to mate with a printed circuit board (“PCB”) via solder bumps; and
a second die enclosed in a wafer scale package and electrically connected to a surface of the first die facing the PCB to form a die stack.

2. The device of claim 1, wherein the second die is electrically connected to the first die using a connection selected from a group consisting of solder bumps, gold studs and anisotropic conduction adhesive.

3. The device of claim 1, wherein the solder bumps have a pitch approximately between 0.3 mm and 0.5 mm.

4. The device of claim 1, wherein the second die fits between the first die and the system PCB.

5. The device of claim 1, wherein the second die is electrically connected to the surface of the first die using wirebonds.

6. A device, comprising:
a first die enclosed in a wafer scale package and comprising a plurality of through-die vias, wherein a first surface of said first die is adapted to mate with a PCB via solder bumps; and
a second die enclosed in a wafer scale package and electrically connected to an active surface of the first die that is opposite the first surface;
wherein the first surface of the first die comprises a metallization pattern to transfer electrical signals between the through-die vias and the solder bumps.

7. The device of claim 6, wherein the second die is electrically connected to the first die using a connection selected from a group consisting of solder bumps, gold studs and anisotropic conduction adhesive.

8. The device of claim 6, wherein the solder bumps are approximately between 0.3 mm and 0.5 mm in pitch.

9. The device of claim 6, further comprising a third die electrically connected to the surface of the first die facing the system PCB.

10. The device of claim 9, wherein the third die is located between the first die and the system PCB.

11. The device of claim 6, wherein the second die is electrically connected to the active surface of the first die using wirebonds.

12. The device of claim 6, further comprising:
a metallization pattern on a surface of the second die facing away from the PCB; and
a third die electrically connected to said metallization pattern.

13. A method, comprising electrically connecting a daughter die to a surface of a mother die adapted to mate with a PCB, said surface facing the system PCB, said dies enclosed in wafer scale packages.

14. The method of claim 13, wherein electrically connecting a daughter die comprises using wirebonds.

15. The method of claim 14, further comprising covering the wirebonds with any of a group consisting of potting material and underfill material.

16. The method of claim 13, wherein electrically connecting the daughter die comprises using a connection selected from a group consisting of solder bumps, gold studs and anisotropic conduction adhesives.

17. The method of claim 13, wherein electrically connecting the daughter die comprises electrically connecting the daughter die between the mother die and the PCB.

18. The method of claim 13, wherein electrically connecting the mother die to the PCB using solder bumps comprises electrically connecting the mother die to the PCB using solder bumps that are approximately of a 0.5 mm pitch.

19. A method, comprising:
electrically connecting a mother die comprising a plurality of through-die vias to a PCB using solder bumps, said mother die enclosed in a wafer-scale package and comprising a metallization pattern on a surface of the mother die facing the PCB; and
electrically connecting a daughter die to an active surface of the mother die not facing the PCB, said daughter die enclosed in a wafer scale package.

20. The method of claim 19, further comprising electrically connecting a daughter die to the metallization pattern on the mother die.

21. The method of claim 19, wherein electrically connecting the daughter die comprises electrically connecting a daughter die comprising a plurality of through-die vias.

22. The method of claim 21, further comprising electrically connecting a grand-daughter die to a surface of the daughter die not facing the mother die, said surface comprising a metallization pattern.

23. The method of claim 19, wherein electrically connecting the mother die comprising a plurality of through-die vias to the system PCB using solder bumps comprises electrically connecting the mother die comprising a plurality of through-die vias to the system PCB using solder bumps that are approximately between 0.3 mm and 0.5 mm in pitch.

24. The method of claim 19, wherein electrically connecting the daughter die to the active surface of the mother die comprises using a connection selected from a group consisting of solder bumps, anisotropic conduction adhesive and gold studs.
